(19) United States
(12) Patent Application Publication
(10) Pub. No.: US 2006/0067254 A1
(43) Pub. Date: Mar. 30, 2006

(54) Triband passive signal receptor network

(75) Inventors: Riad Mahbub, Apopka, FL (US); Berry Leonard, Apopka, FL (US); Wang-Chang Albert Gu, Longwood, FL (US); Rushad Mehershahi, Orlando, FL (US); Benjamin P. Abbott, Longwood, FL (US)

Correspondence Address: CARL M. NAPOLITANO, PH.D.;ALLEN, DYER, DOPPELT, MILBRATH & GILCHRIST, P.A., 255 SOUTH ORANGE AVE., SUITE 1401, P.O. BOX 3791, ORLANDO, FL, 32802-3791, US

(73) Assignee: Sawtek, Inc., Orlando, FL (US)

(21) Appl. No.: 10/950,958

(22) Filed: Sep. 27, 2004

(51) Int. Cl. H03H 9/00; H04B 1/44; H04B 3/36; H01L 41/00

(52) U.S. Cl. 370/282; 370/293; 333/133; 455/324

(57) ABSTRACT

A surface acoustic wave (SAW) triplexer receives radio frequency signals in three bands and provides output signal components for PCS, GPS, and cellular signal processing ports. The triplexer includes low pass filter and a high pass network operating with an antenna terminal for reception and separation of an incoming signal in a low and high frequency bands, and a SAW filter connected to the input terminal for reception and separation of the incoming signal within a frequency band located between that of the low and the high bands. A low insertion loss bandpass filter is provided by the SAW filter having a transducer and reflectors fabricated on a piezoelectric substrate.

### FIELD OF THE INVENTION

The present invention generally relates to wireless communication systems and more particularly to a multiple frequency band passive signal receptor network.

### BACKGROUND OF THE INVENTION

Dual Band Mobile Phones covering both the Code Division Multiplex Access (CDMA) cellular and the Personal Communication Systems (PCS) bands have been in common use for quite sometime. The cellular band operates in the frequency range from 824-894 MHz while the PCS band covers the higher frequency band of 1850-1990 MHz. Recently, the addition of global position system (GPS) to the mobile phone has significantly enhanced its functionality to provide positioning information with regards to the handset through a systematic network of base-stations and satellites. The GPS operates in a narrow frequency band with center frequency around 1575 MHz. The integration of a GPS function adds a new dimension of complexity to the phone design. One of the requirements of a tri-band phone design is a network that can receive an incoming signal and provide signal separation of three distinctive bands without any significant degradation of signal fidelity.

Various architectures are being implemented in mobile handsets. As illustrated with reference to FIG. 1, by way of example, signal reception networks that incorporates two antennas are well known. Typically, one antenna is tuned for receiving the cellular and PCS bands of frequencies while a second antenna is set for the reception of the GPS signal only. With the desired reduction in phone size, a proper placement of two antennas poses a complicated issue. Such an approach has significant performance and size limitations and hence there is a need to provide a single antenna approach.

A known alternative signal reception network incorporates the use of a two-way switch, as illustrated with reference to FIG. 2. One output of the switch is connected to a diplexer that separates the cellular band from the PCS band signals. The other output of the switch is connected to a bandpass filter covering the GPS frequency band. Yet another switch antenna signal reception network is a three-way switch approach that has three dedicated outputs for the cellular, PCS and GPS frequency bands. However, such switch styled solutions have their drawbacks. The two-throw switch/diplexer solution, illustrated with reference to FIG. 2, has a performance degradation issue because of a cascading of insertion losses of the switch and the diplexer in the critical cellular and PCS frequency bands. On the other hand, the three throw switched solution provides low insertion loss. However, its poor cross-modulation performance is a great concern to phone system design engineers. Both the switched solutions need control lines for the operation of the switches that are generally comprised of PIN or PHEMT diodes. Additional DC blocking capacitors required at the RF ports and bypass capacitors at the control lines typically increase the cost and size of the mobile handset. Typically, a switch may exhibit a further disadvantage in that only a single band is activated at any instant of time. Concurrent reception and transmission of signal components from different bands is not possible.

Hence, it is desirable to have a signal reception network that is passive, requiring no control lines, and able to provide good performance in insertion and rejection, while at the same time meet the small size and cost requirements. It is also desirable to have a signal reception network that can provide simultaneous receive and transmit functionality of the different signal bands.

### SUMMARY OF THE INVENTION

The present invention provides embodiments including a passive signal reception network that can receive and separate a frequency signal into distinct bands. One embodiment includes triplexer having at least a low loss Surface Acoustic Wave (SAW) bandpass filter, a low pass filter and a high pass LC filter forming a passive network that can receive and appropriately separate the signal into three different distinct bands. Another embodiment includes a passive SAW triplexer including a low pass and high pass filtering network connected to an antenna directly or through matching or phasing network for reception and separation of the signal. The triplexer may be optimized to provide low insertion loss for each appropriate receiving signal and maintains substantial attenuation and isolation for the other signals that may be out of band frequency signals. The present invention also provides a SAW triplexer that enables simultaneous reception and transmission of different signal bands.

### BRIEF DESCRIPTION OF THE DRAWINGS

Embodiment of the present invention are herein described by way of example with reference to the accompanying drawings in which:

FIG. 1 is a block diagram illustrating a dual antenna signal reception network known in the art;

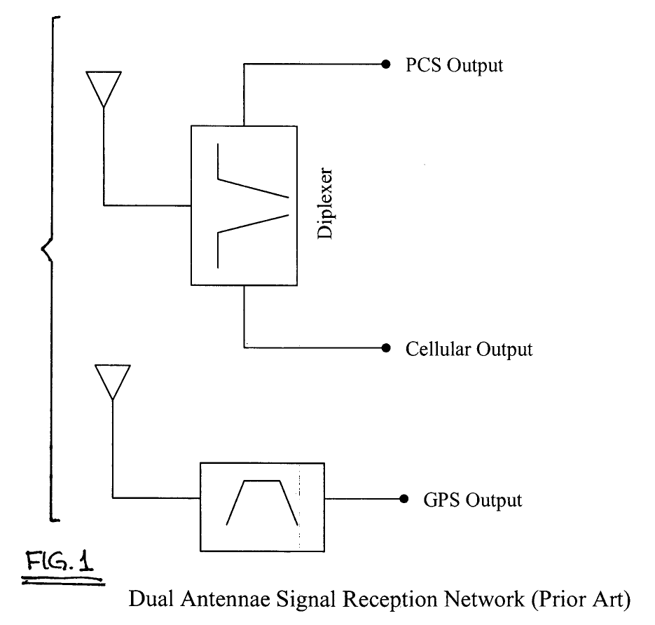

FIG. 2 is a block diagram illustrating an active signal reception network known in the art;

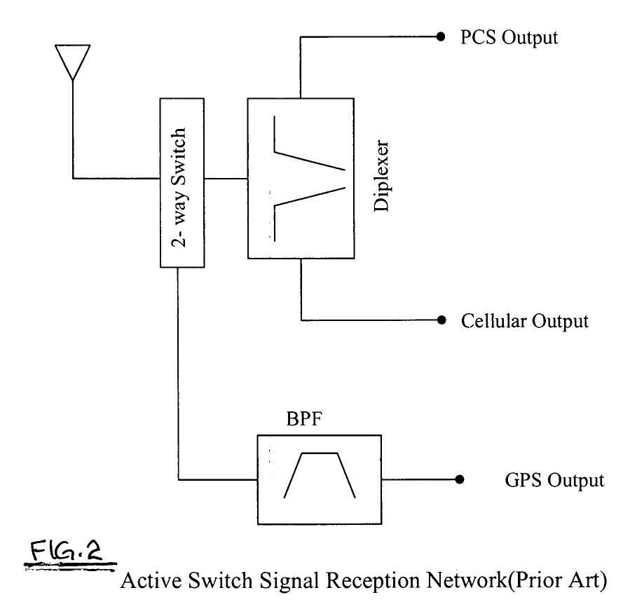

FIG. 3 is a block diagram illustrating a passive signal reception SAW triplexer of the present invention

FIG. 4 is partial plan view of a three-transducer coupled resonator filter;

FIG. 5 is a schematic layout of a ladder filter;

FIG. 6 is a diagrammatical view of a SAW single pole resonator and equivalent schematics:

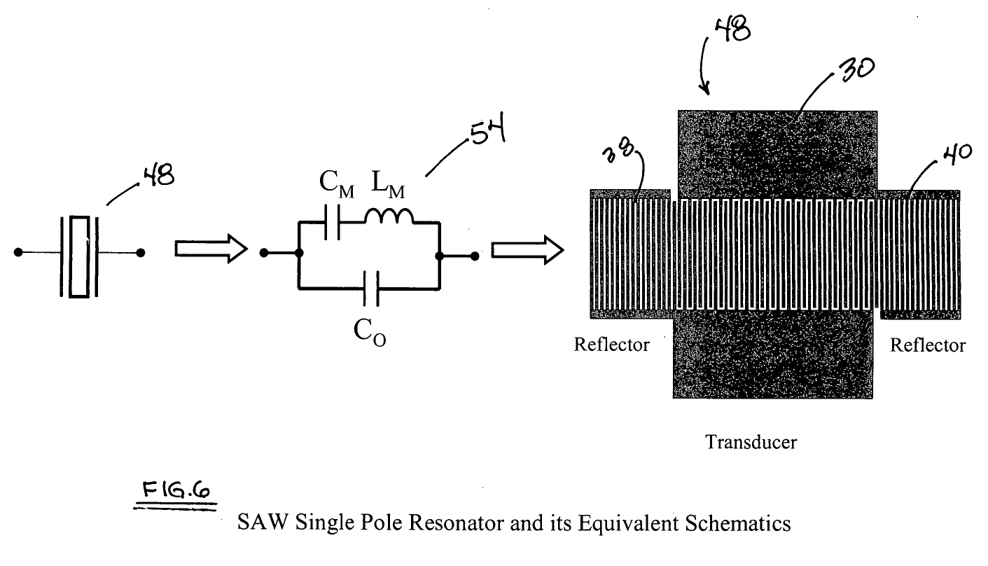

FIG. 7 is a schematic of a SAW triplexer of the present invention;

FIG. 8 is a plot illustrating impedance characteristics of a cellular network;

FIG. 9 is a plot illustrating impedance characteristics of a personal communications service (PCS) network;

FIG. 10 is a plot illustrating impedance characteristics of a global positioning system (GPS) network;

FIG. 11 illustrates a frequency response of a low pass filter;

FIG. 12 illustrates a frequency response of a SAW bandpass filter;

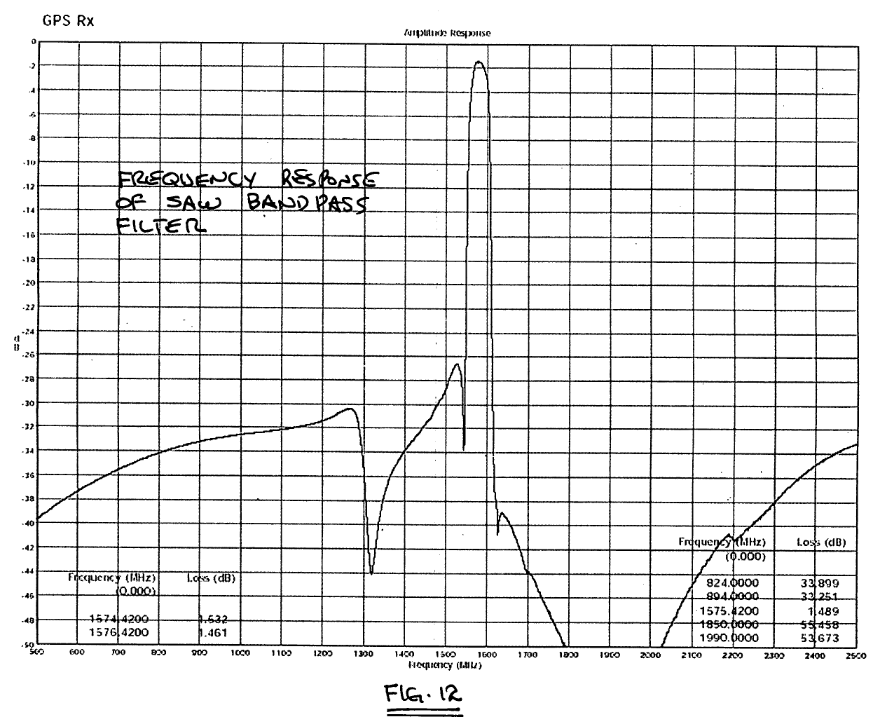

FIG. 13 illustrates a frequency response of a high pass filter; and

FIG. 14 is a partial perspective view of a triplexer assembly.

### DETAILED DESCRIPTION OF THE PREFERRED EMBODIMENTS

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout, and prime notation is used to indicate similar elements in alternate embodiments.

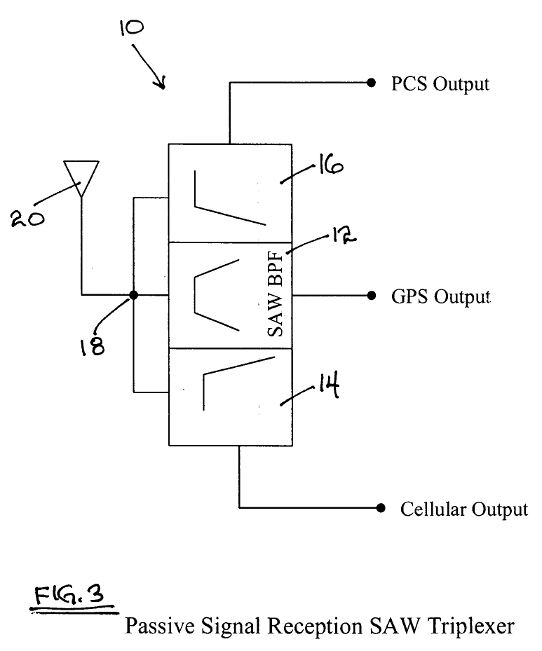

Referring initially to FIG. 3, one embodiment of the present invention includes a SAW triplexer 10, herein illustrated in a block diagram including a SAW bandpass filter 12, a low pass filter 14, and a high pass filter 16 connected directly or indirectly through a phase matching network, which may be located at point 18, to a single antenna 20 for providing signal reception and separation. The low loss SAW bandpass filter 12 covers the GPS frequency band with center frequency around 1575 MHz. The low pass filter 14 receives and separates the cellular band signal frequencies from 824 to 894 MHz, while the high pass filter 16 only allows passage of the PCS frequency band of 1850 to 1990 MHz. Thus, the low pass filter 14 provides a path for the lower frequency components of the signal, while the high pass filter 16 provides the path for the highest frequency band of interest and the mid band signal component is extracted with the help of the SAW bandpass filter 12. Once the signal component is separated, it is then sent to its appropriate port, PCS 22, GPS 24, and cellular 26, for further processing.

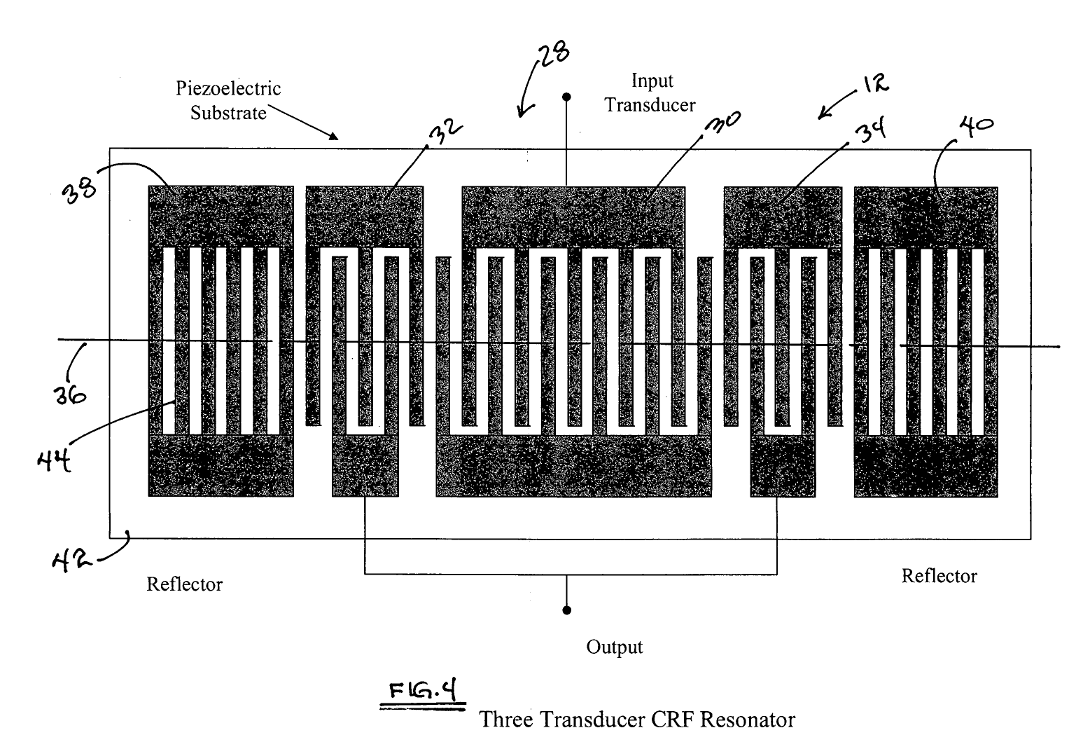

By way of example, the SAW bandpass filter 12 may be a coupled resonator filter (CRF) or a ladder type filter. One coupled resonator SAW filter 28 including three transducers 30, 32, 34 arranged in a side-by-side manner along a longitudinal axis 36 and embedded between the two reflectors 38, 40, is illustrated by way of example with reference to FIG. 4. The transducers and reflectors may be fabricated on a piezoelectric substrate 42 of Lithium Tantalate or Lithium Niobate. The electrode fingers 44 of the transducers 30, 32, 34 and reflectors 38, 40 may be composed of Aluminum metal or Aluminum alloys. The coupled resonator SAW filter 28 is one preferred filter because it exhibits very low insertion loss yet provides a very good out-of-band rejection.

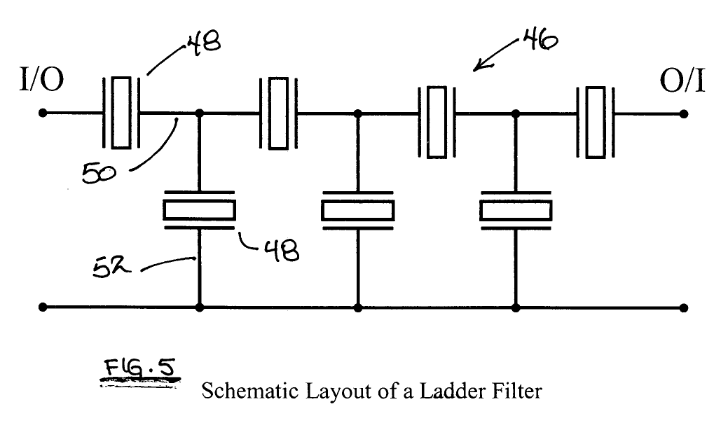

Another SAW bandpass filter 12 that may be used in an embodiment of the triplexer 10, above described, is a SAW ladder filter 46, as illustrated by way of example with reference to FIG. 5. As herein described, the SAW ladder filter 46 may comprise a single pole SAW resonator 48 arranged in either the series arm 50 or the parallel arm 52 for forming a ladder network. The SAW single pole resonator 48, as herein described by way of example, and its equivalent schematic 54 are illustrated with reference to FIG. 5. The resonator 48 may include a single transducer 30 embedded between the two reflectors 38, 40. Both these types of SAW filters are well known to those skilled in the art.

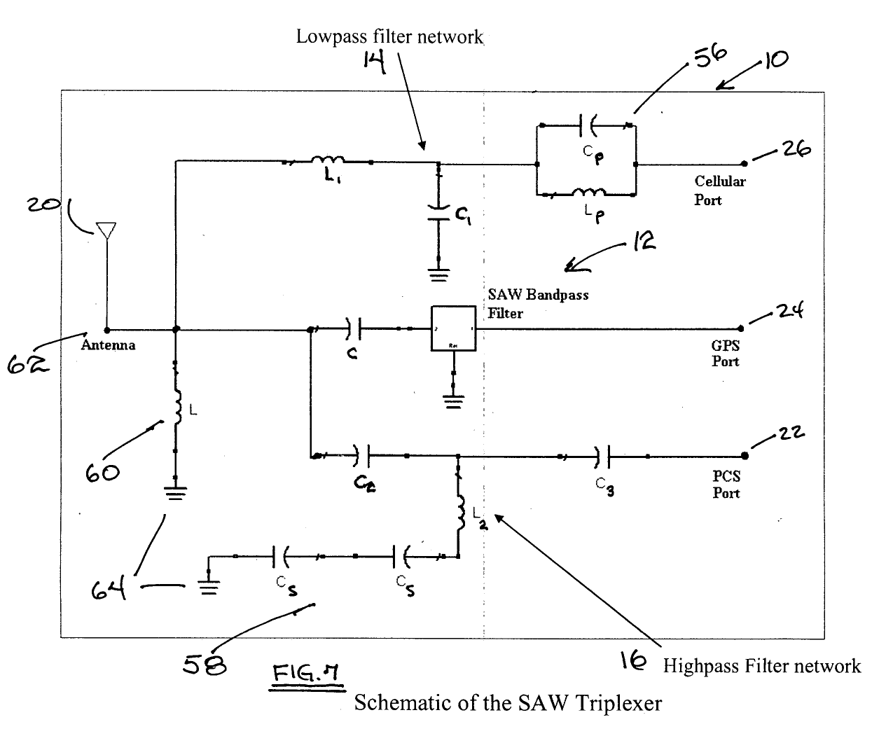

With reference now to FIG. 7, one embodiment of the SAW triplexer 10 is herein illustrated in schematic form by way of example. The low-pass filter 14 and the high-pass filter 16 as herein described may be fabricated with inductive and capacitive (LC) components, as illustrated with L₁ and C₁ for the low pass filter and L₂, C₂, and C₃ for the high pass filter. A parallel tank circuit 56 at the low-pass filter branch (L_{P} and C_{P}) and a series tank circuit 58 at the high-pass filter network (L₂ and C_{S}) provide a strategic “notching” of undesirable frequencies components. The inductor 60 connected from the input 62 to ground 64 provides phasing and impedance matching for the triplexer 10.

The triplexer 10 receives a signal from the antenna 20 and separates its frequency components with minimum loss degradation while able to maintain high signal component fidelity. It provides significant isolation between each of the three frequency bands as above described for the PCS, GPS, and cellular. Thus, the SAW bandpass filter 12, which has a passband of about 10 to 20 MHz, while receiving the GPS frequency component with minimum insertion loss provides substantial attenuation for the cellular and PCS frequency components. These criteria present a critical challenge in the integration of filter networks. Simply incorporating the SAW filter 12 with the low pass and high pass filters 14,16, may allow impedance and phase mismatch to degrade the signal passband. Due to impedance mismatch, reflections from each of the network paths interfere with each other thereby reducing the isolation between each of the three frequency bands. Integration of the filter networks thus requires a stringent phase and impedance matching to ensure signal fidelity and good isolation.

The SAW triplexer 10 uses a very high rejection GPS SAW to improve single tone desensitization performance of the cellular telephone (phone). Single tone desensitization is a measure of the handset's ability to receive a CDMA PCS signal in the presence of a single jamming tone spaced at a given frequency offset from the CDMA signal's center frequency. The single tone desensitization of a phone is affected by a third order inter-modulation product of a low-noise amplifier (LNA) and receiver rejection at a transmitter band of the duplexer. Additionally, the suppression of leakage of power through GPS path is also desirable, especially for those telephone layouts in which the components are so physically close together. The GPS SAW with high rejection at PCS band is thus desirable for the SAW triplexer 10.

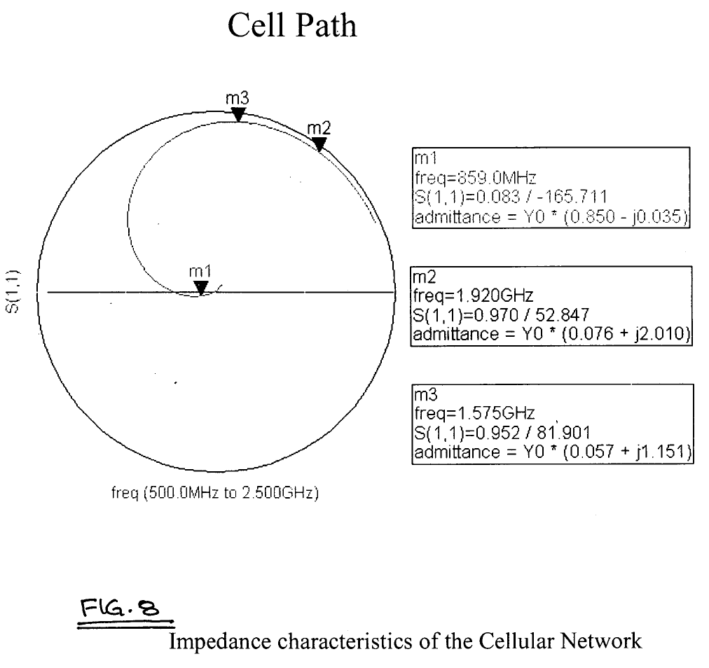

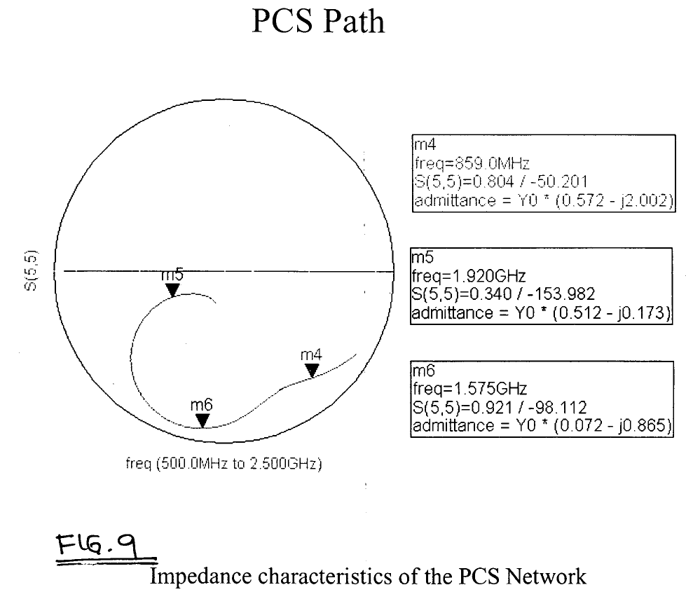

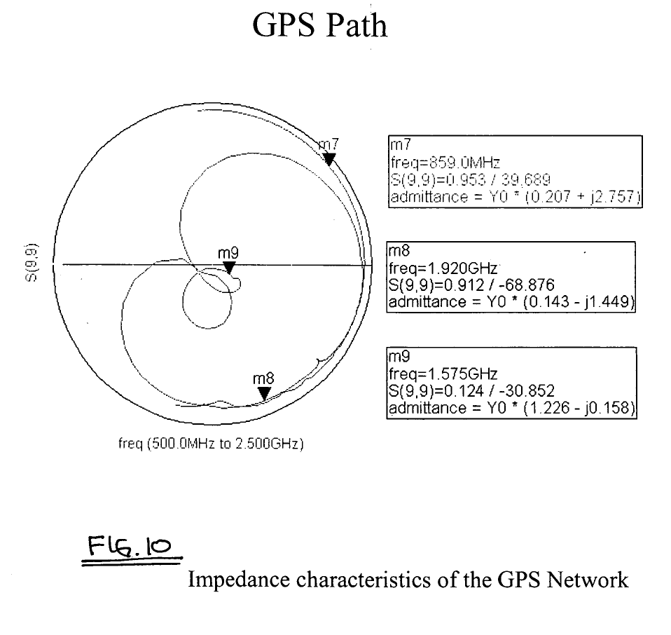

Optimized triplexer performance is provided. With reference now to FIGS. 8, 9, and 10, illustrating impedance/admittance characteristics of the Cellular, PCS and GPS networks, respectively. With reference to FIG. 8, in a cellular network the in-band impedance at m1 is matched closely to 50 ohms (characteristic impedance of one system, by way of example), while the out-of-band impedances at m2 and m3 are maintained very inductive and at relatively high frequency values. For the PCS path (see FIG. 9), as before, the impedance at the center of the PCS band at m5 is set to be about 50 ohms while its out-of-band impedances at m6 and m4 are capacitive. Similarly, for the GPS path (see FIG. 10), the impedance at the GPS center frequency m9 of 1575 MHz is designed to be close to 50 ohms, while its out of band cellular and PCS impedances at m7 and m8 are set away from the characteristics impedance of 50 ohm with m8 being capacitive and m7 inductive. By way of example, at the cellular path, a signal with a cellular frequency component will realize minimal mismatch since impedance at about the center of the low frequency band (m1) is closely matched to the system characteristic impedance of 50 ohms and the impedance at the same low frequency band of the high-pass filter network (m4) being capacitive would cancel with the inductive component of the SAW bandpass filter at the low frequency band(m7). The impedances at m4 and m7 may be targeted to be as close to complex conjugates as possible which assist in impedance cancellation. This would minimize reflections at the passband frequencies arising from other filter sections, thereby enhancing the isolation characteristics of the triplexer 10. To ensure low insertion loss performance, the out-of-band impedances are designed in such a way that the parallel combination of any two out-of-band impedances at a specific frequency band provides very high impedance. Thus, when the high impedance is in parallel to the in-band impedance, the equivalent impedance remains very close to that of the in-band impedance. This reduces mismatch loss and thus ensures low insertion loss performance of the triplexer 10. Yet further, greater rejection of the out-o- band frequencies is enhanced by the incorporation of the series and parallel tank circuits 58, 56 in the high pass and low pass filters 16, 14 as earlier described with reference to FIG. 7.

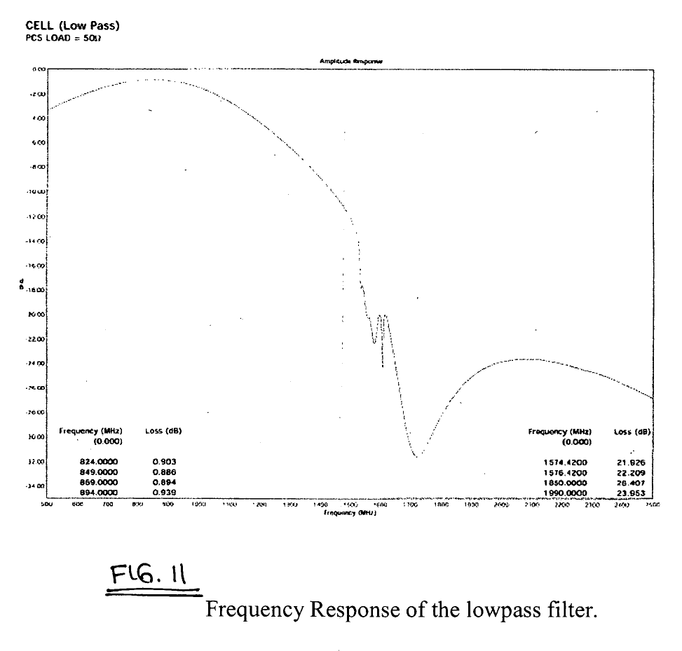

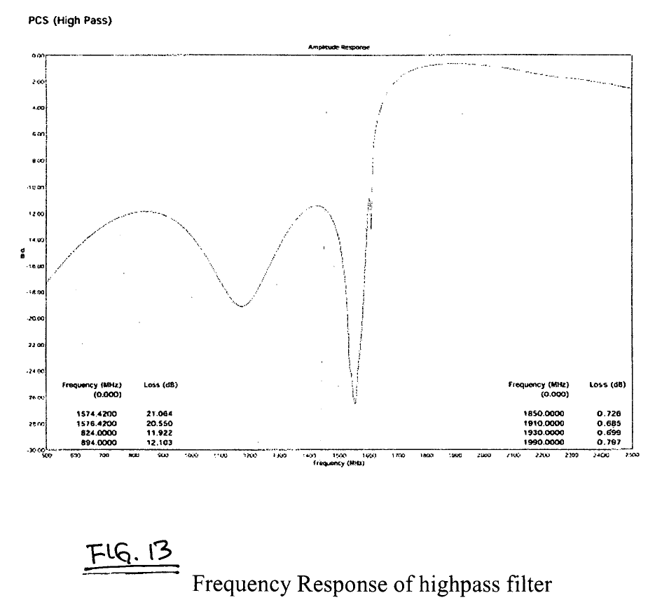

Frequency responses for each of the filter sections, cellular 26, GPS 24, and PCS 26 of the triplexer 10 are illustrated with reference to FIGS. 11,12, and 13, for the low pass 14, SAW bandpass 12, and high pass 16 filters respectively. With continued reference to FIG. 11, the low pass filter 14 exhibits very low loss at the desired frequency band of 824 MHz-894 MHz, while it rejects the GPS and PCS frequency bands. The insertion loss across the desired low frequency band is typically less than 1.0 dB. A notched frequency at around the GPS frequency band is realized by the tank circuit 56 incorporated in the low-pass filter 14 portion of the triplexer 10, earlier described with reference to FIG. 7. Similarly, the high-pass filter 16 provides low insertion loss (typically less than 1 dB) for PCS frequency band and rejects the GPS and cellular band signal components, as illustrated with reference to FIG. 13. As the GPS frequency band is very close to the PCS band, it is necessary that a notched frequency be set at about the GPS frequency with the help of the resonance tank circuit 58 in the high pass filter 16 network earlier described with reference to FIG. 7. The frequency plot of the high pass filter clearly shows a GPS notched frequency at about 1575 MHz. This is accomplished with the series tank circuit 58 in the high pass filter 16 section of the triplexer 10.

As herein described by way of example, the SAW bandpass filter 12 may be the longitudinal coupled resonator 28 earlier described with reference to FIG. 4. The SAW resonator,28 has an input transducer 30 and two parallel connected output transducers 32, 34 embedded between the reflectors 38, 40 forming multiple resonances that can couple with each other for providing a low loss bandpass filter. The insertion loss of the filter 28 is less than 1.5 dB while the rejections at the cellular frequency band and PCS band is greater than 25 dB. The high out of band rejection at the high-pass filter frequencies as achieved by the SAW bandpass filter is very desirable for providing better isolation. The bandpass filter 28 has a dimension of 2.5 mm×2.1 mm×1.5 mm. SAW filters thus provide excellent loss and very good close in rejection in a very small size.

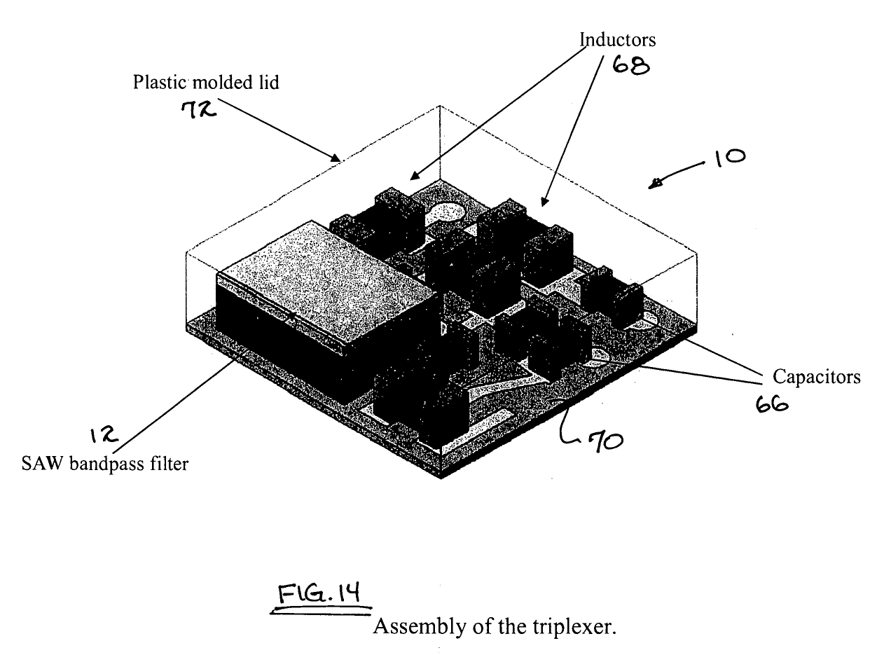

One embodiment of the triplexer 10 including components as above described and in keeping with the teachings of the present invention is illustrated with reference to FIG. 14. Ceramic chip capacitors 66, inductors 68, and the SAW bandpass filter 12 are mounted on a direct printed copper base substrate 70. However, any organic or ceramic substrate may be used for the printed circuit substrate where passives may be embedded or integrated in the substrate. While chip inductors 68 and capacitors 66 are used in the example of the embodiment, any type of reasonably high Q inductor or capacitor may be used. The assembly of components may be sealed with a lid 72 to facilitate further integration of the triplexer 10 into a mobile phone system. The lid 72 may take any form including, but not limited to, a metal lid or plastic over-mold compound. However, it will be understood by those skilled in the art that a lid may not be needed for all applications. By way of further example, size reduction may be achieved by embedding some of the inductors and capacitors within a Low Temperature Co-fired Ceramic (LTCC) substrate or through integration involving other substrate technologies.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

That which is claimed is:

1. A surface acoustic wave (SAW) triplexer useful in receiving radio frequency signals in at least three bands and providing output signal components to signal processing ports, the triplexer comprising:
a low pass filter network suitable for operating with an input terminal for reception and separation of an incoming signal in a low frequency band;
a high pass filter network operable with the input terminal for reception and separation of the incoming signal in a high frequency band; and
a surface acoustic wave (SAW) filter for connecting to the input terminal for reception and separation of the incoming signal at a frequency band located between that of the low and the high bands of the signal, wherein the SAW filter comprises at least one transducer and reflectors fabricated on a piezoelectric substrate for providing a low insertion loss bandpass filter.

2. The triplexer according to claim 1, wherein at least one of the low pass, high pass, and SAW filters is connected to the input terminal through a phase matching network.

3. The triplexer according to claim 1, wherein a characteristic of the low pass filter network includes an impedance close to a system characteristic impedance at the low frequency band, and an impedance at the low frequency band of the SAW filter is inductive while the impedance at the low frequency band for the high pass filter network is capacitive.

4. The triplexer according to claim 1, wherein the impedance at a center frequency of the SAW bandpass filter network is close to a system characteristic impedance within which the triplexer is operable and an out of band impedance at the low frequency band is inductive and the impedance at the high frequency band is capacitive.

5. The triplexer according to claim 1, wherein a rejection of the SAW bandpass filter at the frequency band of the high pass filter is greater than 25 dB.

6. The triplexer according to claim 1, wherein a minimum insertion loss of the low pass filter, the SAW bandpass filter, and the high pass filter is less than 2.0 dB.

7. The triplexer according to claim 1, wherein the triplexer is operable with a concurrent reception and transmission of different signal bands.

8. A surface acoustic wave (SAW) triplexer comprising:
an input terminal providing an incoming signal;
a low pass filter network connected to the input terminal for reception and separation of the incoming signal of a low frequency band having signal components within a frequency band of 824 MHz to 894 MHz;
a high pass filter network connected to the input terminal for reception and separation of the incoming signal of a high frequency band with signal components within a frequency band of 1850 to 1990 MHz; and
a surface acoustic wave (SAW) filter which connected to the input terminal for reception and separation of the incoming signal at a frequency band with signal components within 1570 to 1580 MHz, wherein the SAW filter comprises a transducer and reflector fabricated on a piezoelectric substrate for providing a low insertion loss bandpass filter.

9. The SAW triplexer according to claim 6, wherein a minimum insertion at each of the bands is less than 2.0 dB and a rejection of the SAW bandpass filter at the frequency band ranging from 1850 MHz to 1990 MHz is greater than 25 dB.

10. The SAW triplexer according to claim 6, wherein an impedance of the SAW bandpass filter at about 1575 MHz is approximately 50 ohms, an impedance at the frequency band of 824 MHz to 894 MHz is inductive, and at the frequency band of 1850 to 1990 MHz is capacitive.

11. The SAW triplexer according to claim 6, wherein reception and transmission of the band signals is simultaneous.

12. A triplexer comprising:
an input terminal for providing an incoming signal;
a low pass filter network connected to the input terminal for receiving and separating the incoming signal into a low frequency band;
a high pass filter network connected to the input terminal for receiving and separating the incoming signal into a high frequency band; and
a surface acoustic wave (SAW) filter connected to the input terminal for receiving and separating the incoming signal at a frequency band located between the low and the high frequency bands.

13. The triplexer according to claim 12, further comprising a parallel tank circuit operable within the low pass filter network and a series tank circuit operable within the high pass filter network, the tank circuits operable for providing a notching for undesirable frequencies components.

14. The triplexer according to claim 12, wherein the SAW filter comprises a longitudinal coupled resonator.

15. The triplexer according to claim 14, wherein the resonator comprises an input transducer and two output transducers connected in parallel thereto, wherein the output transducers are embedded between reflectors for forming multiple resonances coupling with each other for providing a low loss bandpass filter.

16. The triplexer according to claim 12, wherein a characteristic of the low pass filter network includes an impedance close to a system characteristic impedance at the low frequency band, and an impedance at the low frequency band of the SAW filter is inductive while the impedance at the low frequency band for the high pass filter network is capacitive.

17. The triplexer according to claim 12, wherein the impedance at a center frequency of the SAW bandpass filter network is close to a system characteristic impedance within which the triplexer is operable and an out of band impedance at the low frequency band is inductive and the impedance at the high frequency band is capacitive.

18. The triplexer according to claim 12, wherein a rejection of the SAW bandpass filter at the frequency band of the high pass filter is greater than 25 dB.

19. The triplexer according to claim 12, wherein a minimum insertion loss of the low pass filter, the SAW bandpass filter, and the high pass filter is less than 2.0 dB.

20. The triplexer according to claim 12, wherein the triplexer is operable with a simultaneous reception and transmission of different signal bands.
